(19) United States
(12) Patent Application Publication
(10) Pub. No.: US 2007/0128758 A1
(43) Pub. Date: Jun. 7, 2007

(54) Semiconductor device and method for fabricating the same

(76) Inventors: Keisuke Tanaka, Osaka (JP); Mitsuyoshi Mori, Kyoto (JP); Takumi Yamaguchi, Kyoto (JP)

Correspondence Address: MCDERMOTT WILL & EMERY LLP, 600 13TH STREET, N.W., WASHINGTON, DC, 20005-3096, US

(21) Appl. No.: 11/605,292

(22) Filed: Nov. 29, 2006

(30) Foreign Application Priority Data
Dec. 1, 2005 (JP) 2005-347640

(51) Int. Cl. H01L 21/00; H01L 29/82

(52) U.S. Cl. 438/50; 257/414

(57) ABSTRACT

A semiconductor device has, on a single substrate, a semiconductor circuit portion and a hollow capacitor portion including a pair of counter electrodes and a hollow part located between the counter electrodes. The hollow part of the hollow capacitor portion is surrounded by an insulating film, and a through hole is formed in the insulating film to communicate with the hollow part. The top surface of the insulating film covering the hollow part is planarized. Part of the insulating film located to the lateral sides of the hollow part supports the other part thereof located on the hollow part and upper one of the counter electrodes.

### CROSS-REFERENCE TO RELATED APPLICATIONS

The disclosure of Japanese Patent Application No. 2005-347640 filed on Dec. 1, 2005 including specification, drawings and claims is incorporated herein by reference in its entirety.

### BACKGROUND OF THE INVENTION

(1) Field of the Invention

The present invention relates to semiconductor devices each having, on a single substrate, a semiconductor circuit portion and a hollow capacitor portion including a pair of counter electrodes and a hollow part located between the counter electrodes.

(2) Description of Related Art

Ultrasonic sensors have been applied to a wide range of fields while taking advantage of their property of being hardly affected by the color and surface conditions of an object. For example, even when an object is transparent in the visible light range, it can be sensed. The reason for this is that ultrasonic waves having frequencies of several tens of kHz through several tens of MHz provide high directivity. For example, devices, such as rangefinders, e.g., fishfinders, and diagnostic systems and flaw detectors both permitting non-destructive examinations have become commercially practical as ultrasonic sensors. In addition, washing machines, welding machines and other machines have become commercially practical as devices using ultrasound. Each of ultrasonic sensors is usually sectioned into a transmitter section for transmitting an ultrasonic wave and a receiver section for receiving the transmitted ultrasonic wave.

However, known ultrasonic sensors become expensive and cannot be reduced in size so much because piezoelectric ceramic vibrators are usually used for receiver sections of known ultrasonic sensors. Furthermore, in order to improve the detectivity of a known ultrasonic sensor, a part of a substrate on which a vibrator is formed must be etched so as to be reduced in thickness. This complicates fabrication process steps for an ultrasonic sensor. Therefore, the range of uses of ultrasonic sensors has been limited.

FIG. 10 is a cross-sectional view illustrating the structure of a receiver section of a known ultrasonic sensor.

Lead zirconate titanate (PZT) that is a ferroelectric ceramic material is formed, as a material of a piezoelectric ceramic vibrator 100, on a substrate. In order to form PZT, a precursor of PZT usually needs to be sintered at high temperatures of 550° C. or more in an oxygen atmosphere. Therefore, an expensive platinum-group based material having difficulty in undergoing microfabrication, such as platinum and iridium, is used as a material of an electrode 101 to prevent the electrode 101 from being insulated due to oxidation thereof during sintering. Furthermore, in order to ensure the sensitivity of the ultrasonic sensor, an opening 102 needs to be formed as follows: A part of the substrate on which the piezoelectric ceramic vibrator 100 is formed is etched from its back surface so as to be reduced in thickness. For example, since an 8-inch Si wafer has a thickness of approximately 750 μm, an etching technique for reducing the film thickness by approximately 1 through 2 μm is not applicable, which is normally used in a process for forming a semiconductor element. Thus, a special process has had to be used to form an opening 102.

Meanwhile, ultrasonic sensors each having, on a semiconductor substrate, a semiconductor circuit portion and a hollow capacitor portion including a pair of electrodes and a hollow part located between the electrodes are disclosed in Japanese Patent No. 2545713, International Publication WO99/65277, Japanese Unexamined Patent Publication No. 2002-250665, and other publications. A hollow part is formed by removing a sacrificial layer by wet etching using hydrofluoric acid or any other substance.

However, when a fine hollow part necessary for a ultrasonic sensor is formed to have a width of approximately several μm through several mm and a gap of several hundreds of nm through several μm, it is very difficult to introduce a liquid etchant, such as hydrofluoric acid, into a sacrificial layer. Even if introduction of a liquid etchant into a sacrificial layer is achieved, the formed hollow part may be destroyed due to the surface tension of the liquid etchant during removal thereof from the hollow part.

### SUMMARY OF THE INVENTION

The present invention is made in order to solve the above-mentioned problems, and its object is to provide a semiconductor device in which a small hollow capacitor having a simple structure can be formed.

In order to achieve the above-mentioned object, a semiconductor device of the present invention has, on a single substrate, a semiconductor circuit portion and a hollow capacitor portion including a pair of counter electrodes and a hollow part located between the counter electrodes. The hollow part of the hollow capacitor portion is surrounded by an insulating film.

With this structure, a small hollow capacitor (ultrasonic sensor) having a simple structure can be easily achieved. Entry of an ultrasonic wave into the semiconductor device allows upper one of the counter electrodes of the hollow capacitor portion to vibrate so that the distance between the upper one thereof and lower one thereof varies, resulting in a variation in the capacitance of the hollow capacitor portion. The variation in the capacitance of the hollow capacitor portion is amplified and detected by a signal processing circuit incorporated into the semiconductor circuit portion. In this way, the semiconductor device works as an ultrasonic sensor.

In one preferred embodiment, the insulating film may include: a first insulating film covering lower one of the counter electrodes of the hollow capacitor portion; a second insulating film covering the hollow part of the hollow capacitor portion formed on the first insulating film; and a third insulating film covering upper one of the counter electrodes formed on the second insulating film.

When a sacrificial layer previously formed in a region of the hollow capacitor portion to be formed with the hollow part is etched away to form the hollow part, the above-mentioned structure can prevent other parts of the hollow capacitor portion than the sacrificial layer, such as the counter electrodes, from being etched away.

In one preferred embodiment, a first hole may be formed to pass through the third insulating film and the second insulating film and communicate with the hollow part. This allows an etchant for the formation of the hollow part to be easily introduced into the sacrificial layer.

In one preferred embodiment, a second hole may be formed to pass through at least the third insulating film and the upper one of the counter electrodes and communicate with the hollow part. This allows a larger amount of etchant to be introduced into the sacrificial layer. Therefore, a hollow part can be easily formed.

The wall of the second hole is preferably covered with a protective film. When the sacrificial layer is to be etched away to form a hollow part, the upper one of the counter electrodes or other components can be prevented from being also etched away.

Preferably, the insulating film and the protective film are made of silicon oxide, the counter electrodes of the hollow capacitor portion are made of polycrystalline silicon, and the upper one of the counter electrodes is vertically interposed between silicon nitride films. This allows the ceiling of the hollow part to be fixed regardless of the type and shape of the upper electrode.

It is preferable that the semiconductor device further includes a charge retention layer between the upper electrode and the hollow part and the charge retention layer is surrounded by the insulating film. This can increase the change in the voltage between the counter electrodes of the hollow capacitor portion according to a change in the distance between the electrodes during reception of an ultrasonic wave, resulting in improved receiver sensitivity.

Another semiconductor device of the present invention includes: a hollow capacitor including a fixed electrode formed on a substrate, a hollow part and a movable electrode; a first insulating film covering the substrate and the fixed electrode; and a second insulating film covering the first insulating film and the hollow part. The hollow part is formed on a part of the first insulating film located on the fixed electrode, the movable electrode is formed on a part of the second insulating film located on the hollow part, and the top surface of the second insulating film is planarized.

With this structure, a part of the second insulating film and the movable electrode both located immediately above the hollow part can be supported by a thick part of the second interlayer dielectric located to the lateral sides of the hollow part. This can prevent the part of the second insulating film and the movable electrode both located immediately above the hollow part from being bent and blocking the hollow part.

In one preferred embodiment, a third insulating film may be further formed to cover the second insulating film and the movable electrode.

In one preferred embodiment, a through hole may be further formed in the second and third insulating films to communicate with the hollow part.

In one preferred embodiment, the hollow part may have one or more linking passageways horizontally extending from one or more associated ends of the hollow part toward the second insulating film, and the through hole may communicate with the linking passageways. This structure can increase the area of a thick part of the second insulating film located to the lateral sides of the hollow part. In this way, the part of the second insulating film and the movable electrode both located immediately above the hollow part can be more firmly supported.

It is preferable that the hollow part is rectangular and the linking passageways horizontally extend from the ends of the hollow part toward the second insulating film such that the hollow part and the linking passageways form the shape of a cross.

A method for fabricating a semiconductor device according to the present invention includes the steps of: forming a fixed electrode on a substrate; forming a first insulating film to cover the substrate and the fixed electrode; forming a sacrificial layer on part of the first insulating film located on the fixed electrode; forming a second insulating film to cover the first insulating film and the sacrificial layer; planarizing the top surface of the second insulating film such that a part of the second insulating film left on the sacrificial layer has a predetermined thickness; forming a movable electrode on a part of the second insulating film located on the sacrificial layer; forming a third insulating film to cover the second insulating film and the movable electrode; forming a through hole to pass through the second and third insulating films and reach the sacrificial layer; and etching away the sacrificial layer through the through hole, thereby forming a hollow part in the second insulating film. The fixed electrode, the hollow part and the movable electrode form a hollow capacitor.

In one preferred embodiment, the sacrificial layer may have a portion horizontally extending from the end of the sacrificial layer toward the second insulating film, and the through hole may reach the extending portion of the sacrificial layer.

### BRIEF DESCRIPTION OF THE DRAWINGS

FIG. 1A is a cross-sectional view illustrating the structure of a semiconductor device according to a first embodiment of the present invention, and FIG. 1B is a plan view of FIG. 1A.

FIG. 2A through 4A are cross-sectional views illustrating process steps in a fabrication method for a semiconductor device according to the first embodiment of the present invention, and FIG. 4B is a plan view of FIG. 4A.

FIG. 5 is a cross-sectional view illustrating a cross-sectional view illustrating a semiconductor device according to a modification of the first embodiment.

FIG. 6 is a cross-sectional view illustrating the structure of a semiconductor device according to a second embodiment of the present invention.

FIGS. 7A through 8B are cross-sectional views illustrating process steps in a fabrication method for a semiconductor device according to the second embodiment of the present invention.

FIG. 9 is a cross-sectional view illustrating a semiconductor device according to a modification of the second embodiment.

FIG. 10 is a cross-sectional view illustrating the structure of a known ultrasonic sensor.

### DETAILED DESCRIPTION OF THE INVENTION

Best modes for carrying out the invention will be described hereinafter with reference to the drawings. Embodiments described below represent examples used to clarify the structures and effects of the present invention. The present invention is not limited to the embodiments described below.

### EMBODIMENT 1

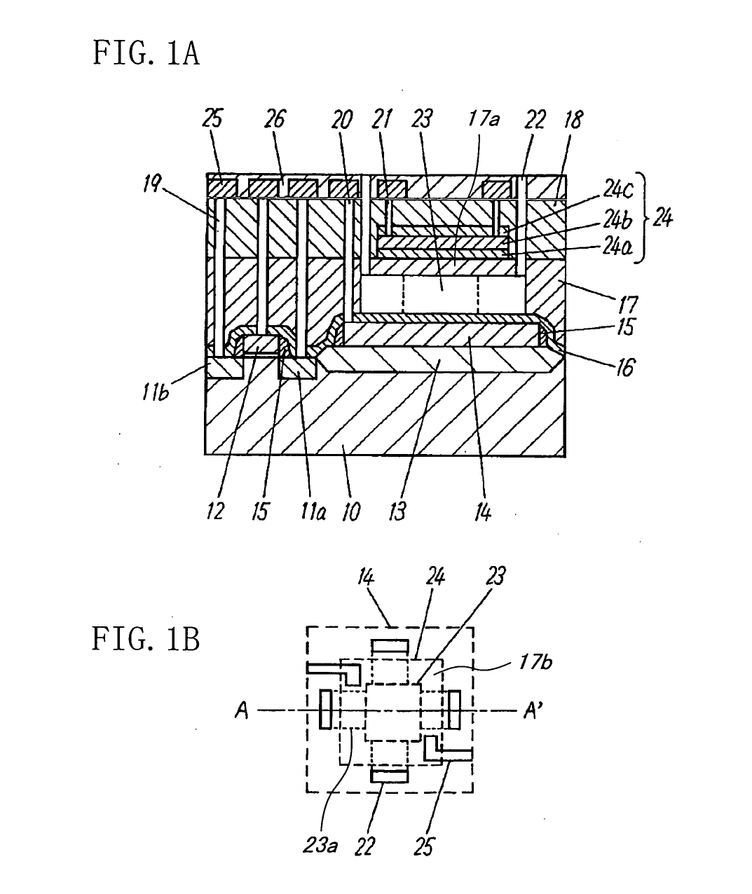

A semiconductor device (ultrasonic sensor) according to a first embodiment will be described with reference to FIGS. 1A through 5.

[Structure of Ultrasonic Sensor]

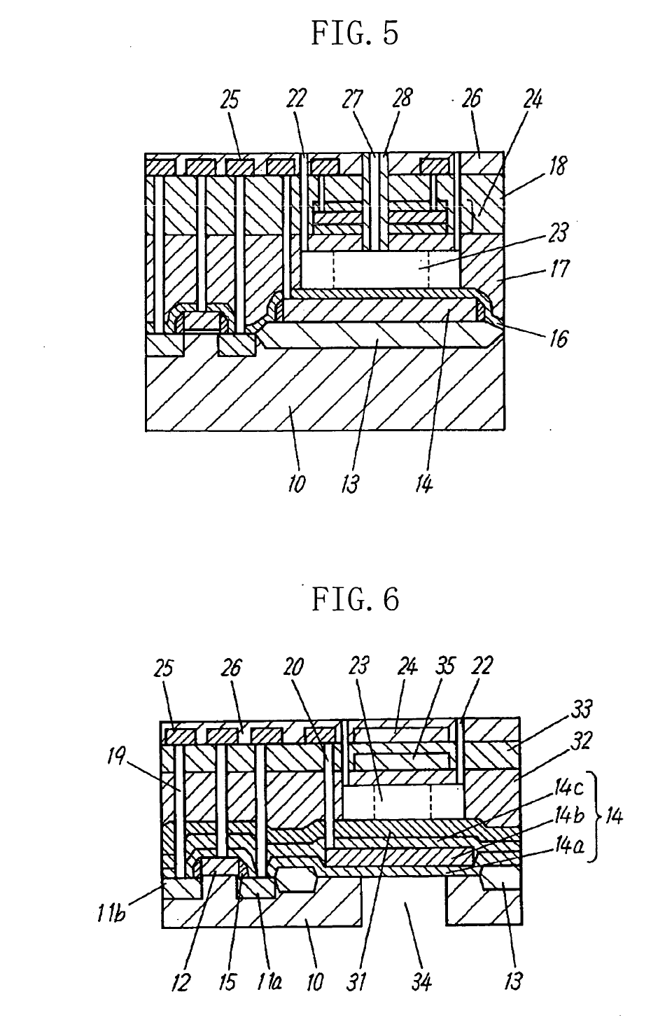

FIG. 1A is a cross-sectional view schematically illustrating the structure of an ultrasonic sensor according to this embodiment, and FIG. 1B is a plan view illustrating a hollow capacitor portion of the ultrasonic sensor according to this embodiment. FIG. 5 is a cross-sectional view illustrating the structure of an ultrasonic sensor according to a modification of this embodiment.

As illustrated in FIG. 1A, the ultrasonic sensor of this embodiment includes a hollow capacitor portion which has an upper electrode (movable electrode) 24 and a lower electrode (fixed electrode) 14 opposed to the upper electrode 24 and a semiconductor circuit portion which includes an amplifier circuit, a noise reduction circuit, an output circuit, and other circuits each having a field-effect transistor and other elements and is integrated with the hollow capacitor portion. FIG. 1A illustrates a single hollow capacitor portion and a single transistor of a single semiconductor circuit portion. However, a plurality of hollow capacitor portions may be arranged in an array. In this case, select transistors capable of arbitrarily selecting the hollow capacitor portions are connected to the hollow capacitor portions. FIG. 1A is a cross-sectional view taken along the line A-A′ passing through the principal part of the hollow capacitor portion in FIG. 1B.

As illustrated in FIG. 1A, a source region 11a and a drain region 11b are formed in the top surface of a p-type silicon substrate 10 by diffusing an n-type impurity thereinto. An isolation region 13 made of a thick oxide film is formed in part of the p-type silicon substrate 10 located to one of the lateral sides of the source region 11a further from the drain region 11b than the other one thereof and one of the lateral sides of the drain region 11b further from the source region 11a than the other one thereof. A first interlayer dielectric (first insulating film) 16, a second interlayer dielectric (second insulating film) 17, a third interlayer dielectric (third insulating film) 18, and a surface protection film 26 are sequentially stacked on the top surface of the silicon substrate 10. The top surface of the second interlayer dielectric 17 is planarized in order to leave a part 17a of the second interlayer dielectric 17 having a predetermined thickness on a hollow part 23 of the hollow capacitor portion that will be described below. The first, second and third interlayer dielectrics 16, 17 and 18 are formed of a silicon oxide film.

A gate electrode 12 is formed on a part of the silicon substrate 10 between the source region 11a and the drain region 11b, and a lower electrode 14 is formed on the isolation region 13. Furthermore, the hollow part 23 is formed on the lower electrode 14 with the first interlayer dielectric 16 interposed therebetween, and introduction holes (through holes) 22 are formed to communicate with the hollow part 23.

As illustrated in FIG. 1B, the hollow part 23 is formed with linking passageways 23a horizontally extending from the edges of the hollow part 23 toward the second interlayer dielectric 17. Each introduction hole 22 communicates with the outer end of associated one of the linking passageways 23a. For example, in FIG. 1B, the hollow part 23 forms a rectangular shape, and a combination of the hollow part 23 and the linking passageways 23a forms the shape of a cross. Lateral end parts of an upper electrode 24 are located on the linking passageways 23a horizontally extending from the edges of the hollow part 23.

With this structure, the part 17a and the upper electrode 24 both located immediately above the hollow part 23 can be supported by a thick part 17b of the second interlayer dielectric 17 located to the sides of the hollow part 23. This can prevent the part 17a located immediately above the hollow part 23 and the upper electrode 24 from being bent and blocking the hollow part 23.

Since the hollow part 23 is formed with the linking passageways 23a horizontally extending from the edges of the hollow part 23, a column formed of a thick part 17b of the second interlayer dielectric 17 can be formed to the outer sides of the linking passageways 23a to support the upper electrode 24. In this way, the part 17a and the upper electrode 24 both located immediately above the hollow part 23 can be more firmly supported.

The area of the lower electrode 14 is larger than that of the upper electrode 24. The hollow part 23 is covered with a silicon oxide film and has a height of approximately 300 nm through 1 μm and an area of approximately 90 nm×90 nm through 1000 μm×1000 μm. The opening area of each introduction hole 22 is approximately 100 nm (long side)×70 nm (short side) through 800 μm (long side)×10 μm (short side).

An upper electrode film 24b is located on the hollow part 23 so as to be vertically interposed between tension films 24a and 24c. The tension films 24a and 24c and the upper electrode film 24b form the upper electrode 24. The tension films 24a and 24c are made of, for example, a silicon nitride film and each have a smaller thickness than the upper electrode film 24b, i.e., a thickness of approximately 30 nm through 250 nm. The upper electrode film 24b is made of, for example, a polysilicon film and has a thickness of approximately 200 nm through 450 nm. The area of the upper electrode 24 is approximately 100 nm×100 nm through 1100 μm×1100 μm. The area of the lower electrode 14 is approximately 110 nm×110 nm through 1200 μm×1200 μm.

In this embodiment, the hollow part 23 is rectangular and communicates with the introduction holes 22 through the linking passageways 23a which communicate with the hollow part 23 such that a combination of the linking passageways 23a and the hollow part 23 forms the shape of a cross. However, a hollow part 23 may form a circular shape or the shape of a gear, and introduction holes 22 may communicate with arbitrary parts of the hollow part 23.

Contact holes 19 are formed on the source region 11a, the drain region 11b and the gate electrode 12 to reach associated ones of interconnects 25 and filled with tungsten (W) or polysilicon. Sidewalls 15 are formed on the lateral sides of the gate electrode 12 and lower electrode 14.

It is preferable that the lower electrode 14 and the gate electrode 12 are made of the same material and have the same thickness. This allows the lower electrode 14 and the gate electrode 12 to be deposited and patterned at the same time. Therefore, a small semiconductor device having a simpler structure can be achieved. The gate electrode 12 and the lower electrode 14 are made of, for example, a polysilicon film and each have a thickness of approximately 200 nm through 450 nm.

A contact hole 20 is formed also on a part of the lower electrode 14 on which the hollow part 23 is not formed to reach associated one of the interconnects 25 and filled with, for example, tungsten (W) or polysilicon. The contact hole 20 may have a different diameter from each contact hole 19.

Contact holes 21 are formed also on parts of the upper electrode 24 immediately below which the hollow part 23 is not formed to reach associated ones of the interconnects 25 and filled with, for example, tungsten (W) or polysilicon. Each contact hole 21 may have a different diameter from each contact hole 19 and the contact hole 20. For example, the contact hole 19 has a diameter of approximately 0.6 μm through 2.5 μm, the contact hole 20 has a diameter of approximately 0.6 μm through 2.0 μm, and the contact hole 21 has a diameter of approximately 0.4 μm through 1.0 μm.

Alternatively, as illustrated in FIG. 5, another introduction hole 27 may be formed to pass through the upper electrode 24 and reach the hollow part 23. In this case, an approximately 50- through 150-nm-thick wall protection film 28 for protecting the wall of the introduction hole 27 needs to be provided such that the upper electrode 24 is not exposed at a part of the introduction hole 27 passing through the upper electrode 24. The wall protection film 28 is made of, for example, a silicon oxide film. The introduction hole 27 has a diameter of approximately 1 μm through 10 μm. The opening area of the introduction hole 27 is 1% or less of the area of the upper electrode 24.

[Fabrication Method for Ultrasonic Sensor]

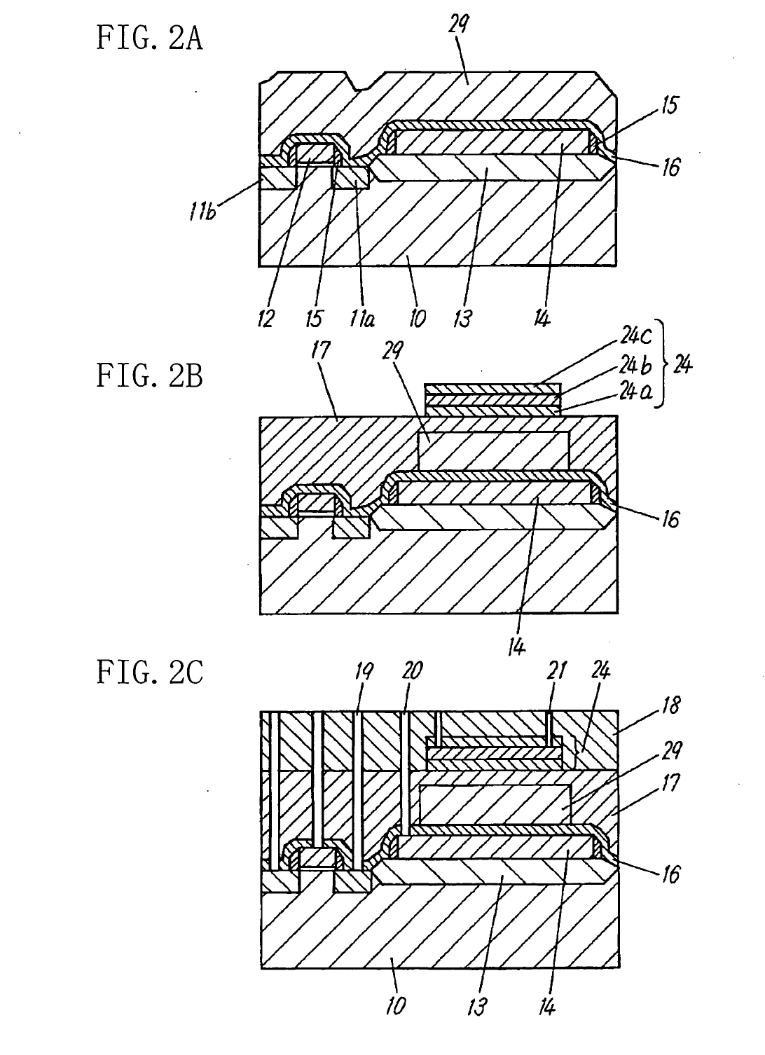

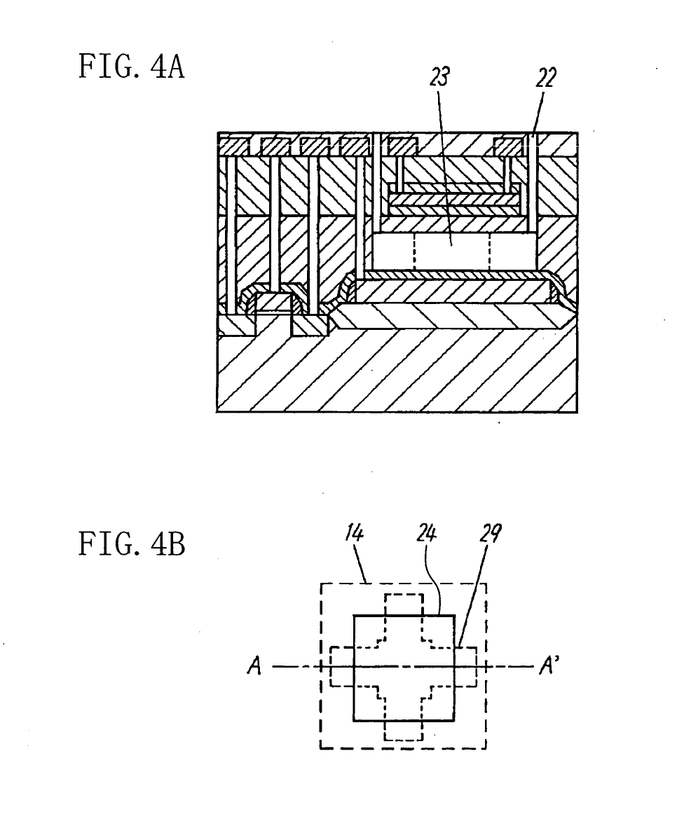

Next, a fabrication method for an ultrasonic sensor according to this embodiment will be described. FIGS. 2A through 4A are cross-sectional views illustrating process steps in the fabrication method for an ultrasonic sensor according to this embodiment. FIG. 4B is a plan view illustrating a hollow capacitor portion of the ultrasonic sensor in FIG. 2B.

First, as illustrated in FIG. 2A, a thick oxide film 13 is selectively formed, as an isolation film, on the top surface of a p-type silicon substrate 10. Subsequently, a gate insulating film and a polysilicon film are deposited to cover the p-type silicon substrate 10 and the thick oxide film 13. The polysilicon film is selectively removed by lithography and dry etching, thereby forming a gate electrode 12 and a lower electrode 14 on the p-type silicon substrate 10 and the thick oxide film 13, respectively.

Subsequently, impurities are implanted into the top surface of the p-type silicon substrate 10 using the gate electrode 12 as a mask, thereby forming a source region 11a and a drain region 11b representing n-type impurity diffusion layers. Thereafter, sidewalls 15 are formed on the lateral sides of the gate electrode 12 and lower electrode 14. Then, a silicon oxide film serving as a first interlayer dielectric 16 and a polysilicon film that will partially become a sacrificial layer 29 are deposited by chemical vapor deposition (CVD) to cover the p-type silicon substrate 10, a field-effect transistor and the lower electrode 14. In order to fabricate a finer transistor, a transistor forming a component of a semiconductor circuit portion of the ultrasonic sensor may take on a salicide structure.

Subsequently, as illustrated in FIG. 2B, the sacrificial layer 29 is shaped, by lithography and dry etching, into a predetermined shape corresponding to a hollow part 23 that will be formed in the hollow capacitor portion. For example, as illustrated in FIG. 4B, the polysilicon film is patterned into the shape of a cross, rectangle, circle or gear or any other shape. Next, a silicon oxide film serving as a second interlayer dielectric 17 is deposited by CVD to cover the sacrifitial layer 29 forming the shape of the hollow part 23 and the first interlayer dielectric 16. Subsequently, the top surface of the deposited second interlayer dielectric 17 is planarized by an etch-back process or a chemical mechanical polishing (CMP) process. The thickness of the second interlayer dielectric 17 immediately after the deposition thereof is set such that a part thereof located on the sacrificial layer 29 has a predetermined thickness after the planarization thereof.

Next, a silicon nitride film, a polysilicon film and a silicon nitride film are sequentially deposited on the second interlayer dielectric 17 by CVD and then subjected to lithography and dry etching, thereby forming an upper electrode 24 including a tension film 24a, an upper electrode film 24b and a tension film 24c.

Subsequently, as illustrated in FIG. 2C, a third interlayer dielectric 18 is deposited by CVD to cover the upper electrode 24 and the second interlayer dielectric 17. Then, the top surface of the third interlayer dielectric 18 is planarized by an etch-back process or CMP. Thereafter, contact holes 21 are formed by lithography and dry etching to pass through the third interlayer dielectric 18 and the tension film 24c and reach the upper electrode film 24b.

Furthermore, contact holes 19 are formed by lithography and dry etching to pass through the third interlayer dielectric 18, the second interlayer dielectric 17 and the first interlayer dielectric 16 and reach the source region 11a, drain region 11b and gate electrode 12 of the transistor. A contact hole 20 is likewise formed to reach the lower electrode 14. Thereafter, a conductive film made of tungsten or polysilicon is deposited by CVD to fill the contact holes 19, 20 and 21. Subsequently, the deposited conductive film is subjected to an etch-back process or a chemical mechanical polishing process, thereby removing part of the conductive film located on the top surface of the third interlayer dielectric 18. In this way, a plurality of contact plugs are formed.

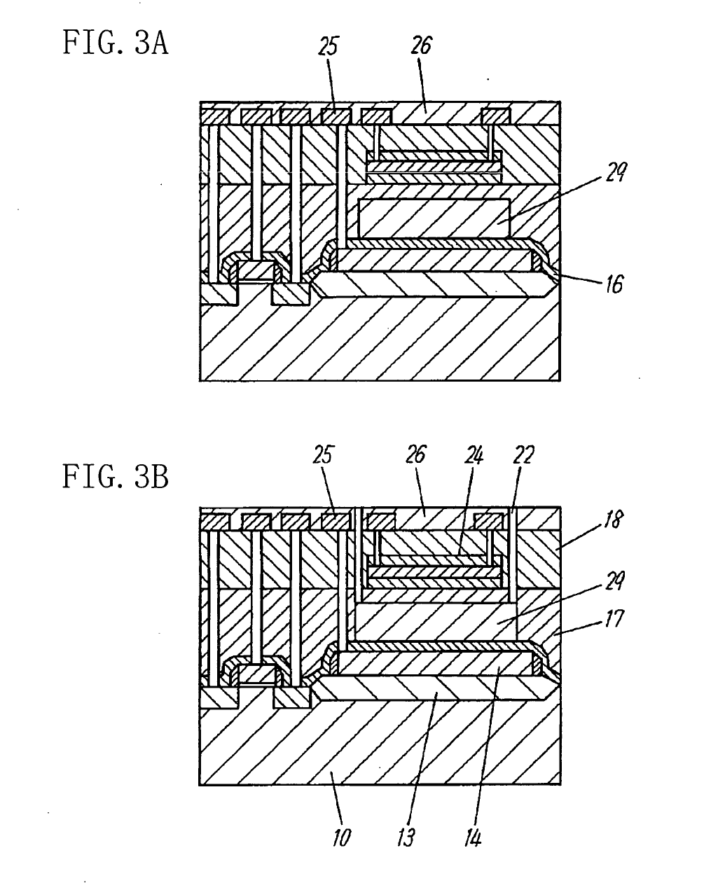

Next, as illustrated in FIG. 3A, for example, titanium, titanium nitride, aluminum, and titanium nitride are deposited on the third interlayer dielectric 18, for example, by sputtering and then subjected to lithography and dry etching, thereby forming interconnects 25.

Moreover, a silicon nitride film is deposited by CVD to cover the third interlayer dielectric 18 and the interconnects 25 and then subjected to lithography and dry etching, thereby removing parts of the silicon nitride film located on pads (not shown) for electrical connection with external devices. In this way, a surface protection film 26 is formed.

Subsequently, as illustrated in FIG. 3B, introduction holes 22 are formed by lithography and dry etching to pass through the surface protection film 26, the third interlayer dielectric 18 and the second interlayer dielectric 17 and reach the sacrificial layer 29 forming the shape of the hollow part 23.

Thereafter, as illustrated in FIG. 4A, the polysilicon film forming the sacrificial layer 29 is completely removed using a gas material capable of etching a polysilicon film, e.g., fluorine trichloride, thereby forming the hollow part 23. In this case, a gas material, such as xenon fluoride, may be used as an etchant for the formation of the hollow part 23. Alternatively, an etchant may be used which is obtained by adding a surface active agent, such as ethanol, to a liquid material, such as fluoronitric acid, and has a reduced surface tension.

Before etching for the formation of the hollow part 23, the following process steps may be added. More specifically, another introduction hole 27 may be formed and then the polysilicon film forming the sacrificial layer 29 may be subjected to etching for the formation of the hollow part 23.

As illustrated in FIG. 5, a through hole is formed by lithography and dry etching to pass through the upper electrode 24 and reach the sacrificial layer 29. Subsequently, a silicon oxide film that will partially become a wall protection film 28 is entirely deposited by CVD to fill the through hole. Next, an introduction hole 27 is formed by lithography and dry etching simultaneously with the formation of the introduction holes 22. While part of the silicon oxide film located on the wall of the introduction hole 27 is left as a wall protection film 28, parts of the silicon oxide film located on the top surfaces of the pads (not shown) for electrical connection with the external devices are removed.

An opening may be formed in the upper electrode 24 immediately after the formation of the upper electrode 24. This allows the opening to be filled with the third interlayer dielectric 18. Therefore, simultaneously with the formation of the introduction holes 22, an introduction hole 27 can be formed at the location corresponding to the opening without adding any process step.

[Superiority of Ultrasonic Sensor]

Since the ultrasonic sensor of this embodiment having the above-described structure has, on the same substrate, a semiconductor circuit portion and a hollow capacitor portion including a pair of counter electrodes and a hollow part located between the counter electrodes, this provides a small ultrasonic sensor having a simple structure.

When an ultrasonic wave enters the ultrasonic sensor, the upper electrode of the hollow capacitor portion vibrates so that the distance between the upper electrode and the lower electrode varies, resulting in a variation in the capacitance of the hollow capacitor portion. The variation in the capacitance of the hollow capacitor portion is amplified and detected by a signal processing circuit incorporated into the semiconductor circuit portion. In this way, the ultrasonic sensor works.

Since introduction holes 22 are formed to reach a sacrificial layer 29 of a hollow capacitor portion and furthermore an introduction hole 27 is formed to pass through an upper electrode 24 of the hollow capacitor portion and reach the sacrificial layer 29, an etchant for the formation of a hollow part 23 can be introduced into the sacrificial layer 29. This facilitates forming the hollow part 23.

Since a hollow part 23 is surrounded by a silicon oxide film, this can prevent an upper electrode 24 and a lower electrode 14 from being etched away during the etching of a sacrificial layer 29 for the formation of the hollow part 23.

Since an upper electrode 24 includes an upper electrode film 24b and tension films 24a and 24c exhibiting strong tensile stress and made of, for example, a silicon nitride film and the upper electrode film 24b is vertically interposed between the tension films 24a and 24c, the upper electrode 24 can independently serve as the ceiling of a hollow part 23 regardless of the type and shape of the upper electrode 24. Since no contact hole 21 is formed in a part of the upper electrode 24 located on the hollow part 23, this facilitates vibrating the upper electrode 24 and thus improves the sensitivity of the ultrasonic sensor.

The sizes of counter electrodes of a hollow capacitor portion are set such that a lower electrode 14 becomes larger than an upper electrode 24. Therefore, a contact hole 20 can be easily formed to provide electrical connection between the lower electrode 14 and associated one of interconnects 25.

Since a lower electrode 14 is made of the same material as a gate electrode 12 and has the same thickness thereas, this allows the lower electrode 14 and the gate electrode 12 to be deposited and patterned at the same time. Therefore, a small semiconductor device having a simpler structure can be achieved.

Since a lower electrode 14 is formed on a thick oxide film 13, elements can be easily isolated from each other.

Since contact holes 19 formed in a semiconductor circuit portion, a contact hole 20 reaching a lower electrode 14 of a hollow capacitor portion, and contact holes 21 reaching an upper electrode film 24b of the hollow capacitor portion are allowed to have different depths and different diameters, they can each have the aspect ratio best suited to making electrical contact with associated one of components.

### EMBODIMENT 2

A semiconductor device (ultrasonic sensor) according to a second embodiment will be described with reference to FIGS. 6 through 9.

[Structure of Ultrasonic Sensor]

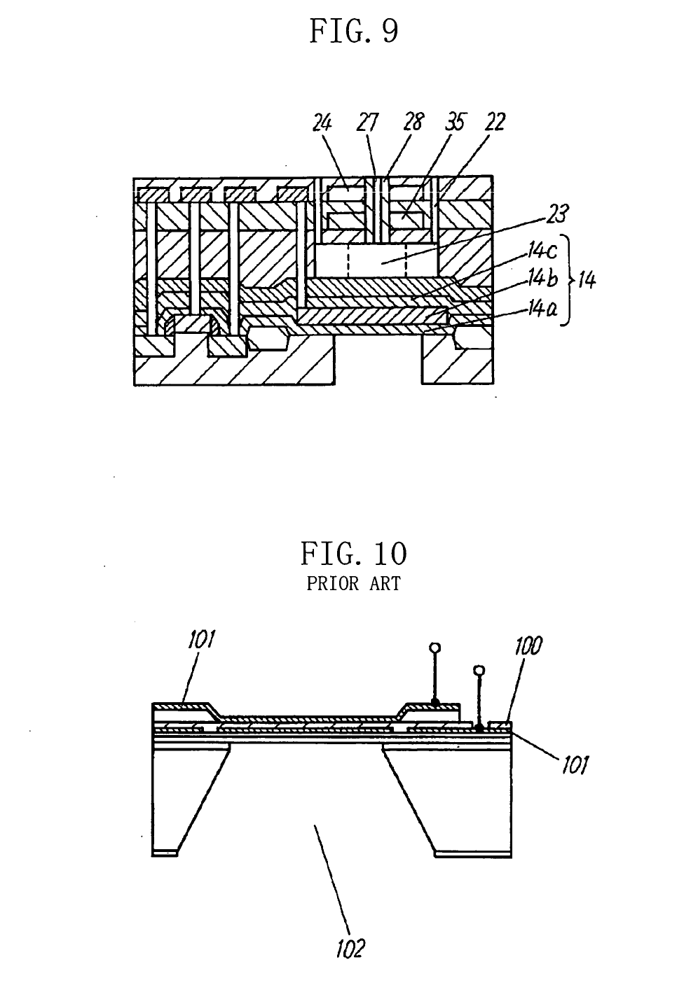

The structure of an ultrasonic sensor will be described with reference to FIGS. 6 and 9. FIG. 6 is a cross-sectional view illustrating the structure of an ultrasonic sensor according to this embodiment. FIG. 9 is a cross-sectional view illustrating the structure of an ultrasonic sensor according to a modification of this embodiment.

As illustrated in FIG. 6, the ultrasonic sensor of this embodiment includes a hollow capacitor portion which has an upper electrode, a lower electrode opposed to the upper electrode and a charge retention material and a semiconductor circuit portion which includes a field-effect transistor element and other elements and is integrated with the hollow capacitor portion. FIG. 6 illustrates a single hollow capacitor portion and a single transistor of a single semiconductor circuit portion. However, a plurality of hollow capacitor portions may be arranged in an array. In this case, an ultrasonic sensor may be configured such that select transistors capable of arbitrarily selecting the hollow capacitor portions are connected to the hollow capacitor portions, thereby integrating the plurality of hollow capacitor portions.

As illustrated in FIG. 6, a source region 11a and a drain region 11b are formed in the top surface of a p-type silicon substrate 10 by diffusing an n-type impurity thereinto. An isolation region 13 of a thick oxide film is formed to one of the lateral sides of the source region 11a further from the drain region lib than the other one thereof and one of the lateral sides of the drain region 11b further from the source region 11a than the other one thereof. A first interlayer dielectric 31, a second interlayer dielectric 32, a third interlayer dielectric 33, and a surface protection film 26 are sequentially stacked on the top surface of the substrate 10. The first, second and third interlayer dielectrics 31, 32 and 33 are formed of a silicon oxide film.

An isolation region 13 is formed in a part of the substrate 10 between the semiconductor circuit portion and the hollow capacitor portion. A lower electrode film 14b is formed on a part of the substrate 10 surrounded by the isolation region 13 while being vertically interposed between tension films 14a and 14c. These films 14a, 14b and 14c form a lower electrode 14.

A through hole 34 is formed in a part of the silicon substrate 10 located under the lower electrode 14. A hollow part 23 of the hollow capacitor portion is formed on the lower electrode 14 with the first interlayer dielectric 31 interposed therebetween and provided with linking passageways 23a horizontally extending from the edges of the hollow part 23 toward the second interlayer dielectric 32. Introduction holes 22 communicate with the outer ends of the linking passageways 23a. The hollow part 23 forms a rectangular shape, and a combination of the hollow part 23 and the linking passageways 23a forms the shape of a cross. The tension films 14a and 14c are made of, for example, a silicon nitride film and each have a smaller thickness than the lower electrode film 14b, i.e., a thickness of approximately 30 nm through 250 nm. The lower electrode film 14b is made of, for example, a polysilicon film and has a thickness of approximately 200 nm through 450 nm. While the area of the upper electrode 24 is approximately 100 nm×100 nm through 1100 μm×1100 μm, the area of the lower electrode 14 is approximately 110 nm×110 nm through 1200 μm×1200 μm. The opening area of each introduction hole 22 is approximately 100 nm (long side)×70 nm (short side) through 800 μm (long side)×10 μm (short side).

The lower electrode 14 has a larger area than the upper electrode 24. The hollow part 23 is surrounded by a silicon oxide film. A charge retention material 35 is formed between the hollow part 23 and the upper electrode 24 and surrounded by the second interlayer dielectric 32 and the third interlayer dielectric 33. The hollow part 23 has a height of approximately 300 nm through 1 μm and an area of approximately 90 nm×90 nm through 1000 μm×1000 μm.

In this embodiment, the hollow part 23 is rectangular and communicates with the introduction holes 22 through the linking passageways 23a such that a combination of the linking passageways 23a and the hollow part 23 forms the shape of a cross. However, a hollow part 23 may form a circular shape or the shape of a gear, and introduction holes 22 may communicate with arbitrary parts of the hollow part 23.

Contact holes 19 are formed on the source region 11a, the drain region 11b and the gate electrode 12 to reach associated ones of interconnects 25 and filled with tungsten (W) or polysilicon. Sidewalls 15 are formed on the lateral sides of the gate electrode 12 and lower electrode 14.

The lower electrode 14 and the gate electrode 12 are made of the same material and have substantially the same thickness. Therefore, a small semiconductor device having a simple structure can be achieved. The gate electrode 12 and the lower electrode film 14b are made of, for example, a polysilicon film and each have a thickness of approximately 200 nm through 450 nm.

A contact hole 20 is formed also on a part of the lower electrode 14 on which the hollow part 23 is not formed to reach associated one of the interconnects 25 and filled with, for example, tungsten (W) or polysilicon. The diameter of the contact hole 20 may be different from that of each contact hole 19.

Alternatively, as illustrated in FIG. 9, another introduction hole 27 may be formed to pass through the upper electrode 24 and reach the hollow part 23. In this case, an approximately 50- through 150-nm-thick wall protection film 28 for protecting the wall of the introduction hole 27 needs to be provided such that the upper electrode 24 is not exposed at a part of the introduction hole 27 passing through the upper electrode 24. The wall protection film 28 is made of, for example, a silicon oxide film. The introduction hole 27 has a diameter of approximately 1 μm through 10 μm. The opening area of the introduction hole 27 is 1% or less of the area of the upper electrode 24.

[Fabrication Method for Ultrasonic Sensor]

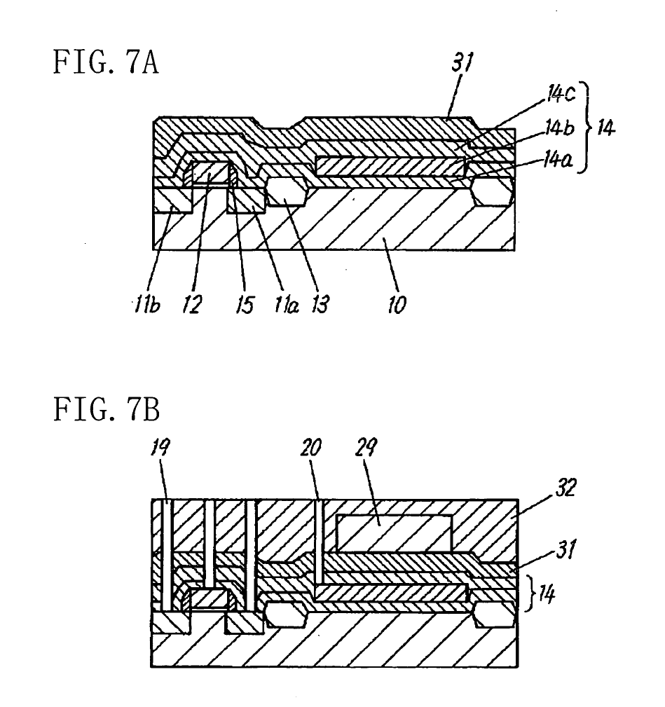

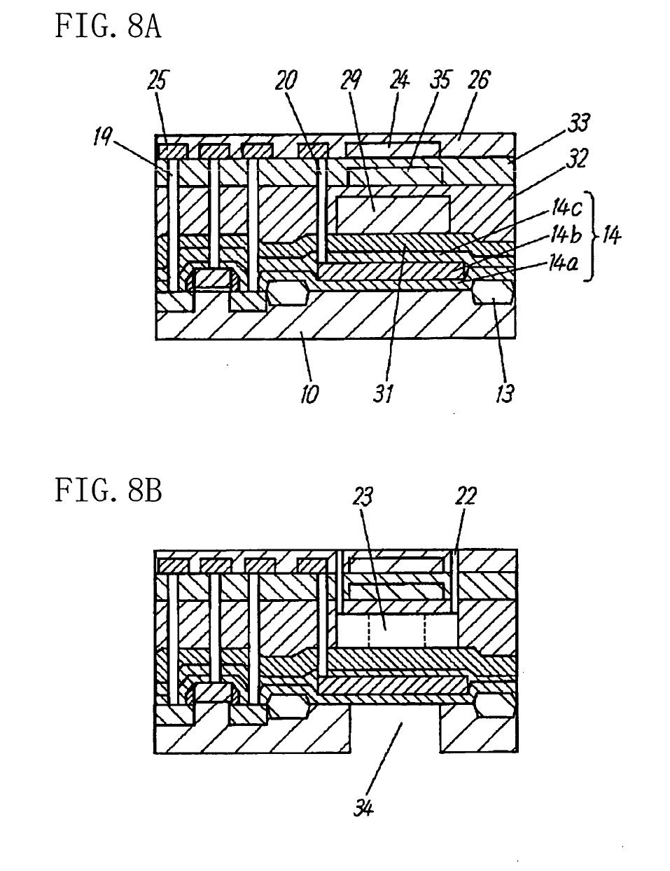

Next, a fabrication method for an ultrasonic sensor according to this embodiment will be described. FIGS. 7A through 8B are cross-sectional views illustrating process steps in the fabrication method for an ultrasonic sensor according to this embodiment.

First, as illustrated in FIG. 7A, a thick oxide film 13 is selectively formed, as an isolation film, on the top surface of a p-type silicon substrate 10. Subsequently, a gate insulating film and a polysilicon film are deposited to cover the p-type silicon substrate 10 and the thick oxide film 13. The polysilicon film is patterned into a gate electrode 12 by lithography and dry etching. Subsequently, impurities are implanted into the top surface of the p-type silicon substrate 10 using the gate electrode 12 as a mask, thereby forming a source region 11a and a drain region 11b representing n-type impurity diffusion layers.

Subsequently, a silicon nitride film serving as a tension film 14a is deposited on the entire surface of the p-type silicon substrate 10 by CVD. Next, a polysilicon film is deposited on the silicon nitride film and patterned into a lower electrode film 14b serving as part of a lower electrode by lithography and dry etching. Subsequently, a silicon nitride film serving as a tension film 14c and a silicon oxide film serving as a first interlayer dielectric 31 are sequentially deposited to cover the tension film 14a and the lower electrode film 14b.

Subsequently, as illustrated in FIG. 7B, a polysilicon film that will partially become a sacrificial layer 29 is entirely deposited on the first interlayer dielectric 31 by CVD. Subsequently, the polysilicon film is patterned into a sacrificial layer 29 having a predetermined shape corresponding to a hollow part 23 of a hollow capacitor portion by lithography and dry etching. Like the first embodiment, the polysilicon film is patterned into the shape of a cross or any other shape. Next, a silicon oxide film serving as a second interlayer dielectric 32 is deposited by CVD to cover the sacrifitial layer 29 forming the shape of the hollow part 23 and the first interlayer dielectric 31. Subsequently, the top surface of the deposited second interlayer dielectric 32 is planarized by an etch-back process or a chemical mechanical polishing (CMP) process. The thickness of the second interlayer dielectric 32 immediately after the deposition thereof is set such that a part thereof located on the sacrificial layer 29 has a predetermined thickness after the planarization thereof.

Next, as illustrated in FIG. 8A, a charge retention material 35 is formed on the second interlayer dielectric 32 by CVD, lithography and dry etching. For example, a Teflon (registered trademark) film or any other film is used as the charge retention film 35. Thereafter, charges are deposited oh the charge retention material 35 by corona discharge, and then a silicon oxide film serving as a third interlayer dielectric 33 is deposited to cover the charge retention material 35. Subsequently, the top surface of the deposited third interlayer dielectric 33 is planarized by an etch-back process or a chemical mechanical polishing (CMP) process. The thickness of the third interlayer dielectric 33 immediately after the deposition thereof is set such that a part thereof located on the charge retention material 35 has a predetermined thickness after the planarization thereof.

Subsequently, contact holes 19 are formed by lithography and dry etching to reach the source region 11a, the drain region 11b and the gate electrode 12 of the transistor. A contact hole 20 is formed by lithography and dry etching to reach the lower electrode film 14b. Thereafter, a conductive film made of tungsten or polysilicon is deposited by CVD to fill the contact holes 19 and 20. Subsequently, the deposited conductive film is subjected to an etch-back process or a chemical mechanical polishing process, thereby removing part of the conductive film located on the top surface of the third interlayer dielectric 33. In this way, a plurality of contact plugs are formed.

Subsequently, for example, titanium, titanium nitride, aluminum, and titanium nitride are sequentially deposited on the third interlayer dielectric 33, for example, by sputtering. The deposited materials are subjected to lithography and dry etching, thereby forming an upper electrode 24 and interconnects 25.

Furthermore, a silicon nitride film is deposited by CVD to cover the upper electrode 24 and the interconnects 25 and then subjected to lithography and dry etching, thereby removing parts of the silicon nitride film located on pads (not shown) for electrical connection with external devices. In this way, a surface protection film 26 is formed.

Next, as illustrated in FIG. 8B, introduction holes 22 are formed by lithography and dry etching to pass through the surface protection film 26, the third interlayer dielectric 33 and the second interlayer dielectric 32 and reach the sacrificial layer 29 forming the shape of the hollow part 23. Subsequently, a resist film (not shown) is formed on the back surface of the wafer by lithography to have an opening under the lower electrode 14 and masks part of the back surface of the wafer except for part thereof exposed at the opening.

Subsequently, the polysilicon film forming the sacrificial layer 29 is completely removed using a gas material, such as fluorine trichloride and xenon fluoride, as an etchant for the formation of the hollow part 23, thereby forming the hollow part 23. Simultaneously, part of the silicon substrate 10 exposed at the opening is also etched away, thereby forming a through hole 34 in part of the silicon substrate 10 located under the lower electrode 14.

Before etching for the formation of the hollow part 23, the following process steps may be added. More specifically, another introduction hole 27 may be formed and then the polysilicon film may be subjected to etching for the formation of the hollow part 23.

As illustrated in FIG. 9, a through hole is formed by lithography and dry etching to pass through the upper electrode 24 and the charge retention material 35 and reach the sacrificial layer 29. Subsequently, a silicon oxide film that will partially become a wall protection film 28 is entirely deposited by CVD to fill the through hole. Next, when an introduction hole 27 is formed in the filled through hole by lithography and dry etching simultaneously with the formation of the introduction holes 22, part of the silicon oxide film located on the wall of the introduction hole 27 is left as a wall protection film 28. Simultaneously, parts of the silicon oxide film located on the top surfaces of pads (not shown) for electrical connection with external devices are removed.

[Superiority of Ultrasonic Sensor]

Since the ultrasonic sensor of this embodiment having the above-described structure has, on the same substrate, a semiconductor circuit portion and a hollow capacitor portion including a pair of counter electrodes and a hollow part located between the counter electrodes, this provides a small ultrasonic sensor having a simple structure.

When an ultrasonic wave enters the ultrasonic sensor, the upper electrode of the hollow capacitor portion vibrates so that the distance between the upper electrode and the lower electrode varies, resulting in a variation in the capacitance of the hollow capacitor portion. The variation in the capacitance of the hollow capacitor portion is amplified and detected by a signal processing circuit incorporated into the semiconductor circuit portion. In this way, the ultrasonic sensor works.

Since introduction holes 22 are formed to reach the sacrificial layer 29 of the hollow capacitor portion and furthermore an introduction hole 27 is formed to pass through the upper electrode 24 of the hollow capacitor portion and reach the sacrificial layer 29, an etchant for the formation of a hollow part 23 can be further introduced into the sacrificial layer 29. This can facilitate forming the hollow part 23.

Since a hollow part 23 and a charge retention material 35 are surrounded by silicon oxide films, this can prevent the charge retention material 35 and a lower electrode 14 from being etched away during the etching of the sacrificial layer 29 for the formation of the hollow part 23.

A charge retention material 35 is formed between an upper electrode 24 of a hollow capacitor portion and a hollow part 23 so as to be surrounded by insulating films. This can increase the variation in voltage between the upper electrode 24 and the lower electrode 14 of the hollow capacitor portion according to the change in the distance between the electrodes during reception of an ultrasonic wave, resulting in improved receiver sensitivity. Since a charge retention material 35 is formed between a hollow part 23 and an upper electrode 24, this can significantly reduce the damage done to the charge retention material 35 due to heat treatment, such as annealing during the formation of an ultrasonic sensor.

Since a charge retention material 35 is placed between counter electrodes, this eliminates the need for a circuit for supplying charges to a capacitor, resulting in a reduced circuit area. This can reduce the size of an ultrasonic sensor.

Since a through hole 34 is formed in a part of the silicon substrate 10 located under a lower electrode 14 of a hollow capacitor portion, this allows an ultrasonic sensor to receive an ultrasonic wave with excellent sensitivity.

Although the present invention was described above using the preferred embodiments, the above description is not limited. The above-mentioned embodiments can be variously modified as a matter of course. For example, in this embodiment, an ultrasonic sensor was exemplified as a semiconductor device including a hollow capacitor. However, the present invention can be applied also to other sound responsive devices, such as a condenser microphone.

As described above, the present invention is useful for supersonic sensors and other devices with which semiconductor circuits are integrated and suitable for not only its use alone but also its installation on various electronic devices and has high industrial applicability.

What is claimed is:

1. A semiconductor device comprising, on a single substrate, a semiconductor circuit portion and a hollow capacitor portion including a pair of counter electrodes and a hollow part located between the counter electrodes,
the hollow part of the hollow capacitor portion being surrounded by an insulating film.

2. The semiconductor device of claim 1, wherein
the insulating film includes:
a first insulating film covering lower one of the counter electrodes of the hollow capacitor portion;
a second insulating film covering the hollow part of the hollow capacitor portion formed on the first insulating film; and
a third insulating film covering upper one of the counter electrodes formed on the second insulating film.

3. The semiconductor device of claim 2, wherein
a first hole is formed to pass through the third insulating film and the second insulating film and reach the hollow part.

4. The semiconductor device of claim 2, wherein
a second hole is formed to pass through at least the third insulating film and the upper one of the counter electrodes and reach the hollow part.

5. The semiconductor device of claim 4, wherein
the wall of the second hole is covered with a protective film.

6. The semiconductor device of claim 5, wherein
the insulating film and the protective film are made of silicon oxide,
the counter electrodes of the hollow capacitor portion are made of polycrystalline silicon, and
the upper one of the counter electrodes is vertically interposed between silicon nitride films.

7. The semiconductor device of claim 1 further comprising
a charge retention layer between upper one of the counter electrodes and the hollow part,
the charge retention layer being surrounded by the insulating film.

8. The semiconductor device of claim 7, wherein
the insulating film includes:
a first insulating film covering lower one of the counter electrodes of the hollow capacitor portion;
a second insulating film covering the hollow part of the hollow capacitor portion formed on the first insulating film; and
a fourth insulating film covering the charge retention layer formed on the second insulating film, and
the upper one of the counter electrodes of the hollow capacitor portion is formed on the fourth insulating film.

9. The semiconductor device of claim 8, wherein
a first hole is formed to pass through at least the second insulating film and reach the hollow part.

10. A semiconductor device comprising:
a hollow capacitor including a fixed electrode formed on a substrate, a hollow part and a movable electrode;
a first insulating film covering the substrate and the fixed electrode; and
a second insulating film covering the first insulating film and the hollow part,
the hollow part being formed on a part of the first insulating film located on the fixed electrode, the movable electrode being formed on a part of the second insulating film located on the hollow part, and the top surface of the second insulating film being planarized.

11. The semiconductor device of claim 10 further comprising
a third insulating film covering the second insulating film and the movable electrode.

12. The semiconductor device of claim 11, wherein
a through hole is formed in the second and third insulating films to reach the hollow part.

13. The semiconductor device of claim 12, wherein
the hollow part has one or more linking passageways horizontally extending from one or more associated ends of the hollow part toward the second insulating film, and
the through hole reaches the linking passageways.

14. The semiconductor device of claim 13, wherein
the hollow part is rectangular, and
the linking passageways horizontally extend from the ends of the hollow part toward the second insulating film such that the hollow part and the linking passageways form the shape of a cross.

15. The semiconductor device of claim 13 or 14, wherein
an end part of the movable electrode is located on each said linking passageway.

16. A method for fabricating a semiconductor device, said method comprising the steps of:
forming a fixed electrode on a substrate;
forming a first insulating film to cover the substrate and, the fixed electrode;
forming a sacrificial layer on part of the first insulating film located on the fixed electrode;
forming a second insulating film to cover the first insulating film and the sacrificial layer;
planarizing the top surface of the second insulating film such that a part of the second insulating film left on the sacrificial layer has a predetermined thickness;
forming a movable electrode on a part of the second insulating film located on the sacrificial layer;
forming a third insulating film to cover the second insulating film and the movable electrode;
forming a through hole to pass through the second and third insulating films and reach the sacrificial layer; and
etching away the sacrificial layer through the through hole, thereby forming a hollow part in the second insulating film,
wherein the fixed electrode, the hollow part and the movable electrode form a hollow capacitor.

17. The method of claim 16, wherein
the sacrificial layer has a portion horizontally extending from an end of the sacrificial layer toward the second insulating film, and
the through hole reaches the extending portion of the sacrificial layer.
